(19) United States
(12) Patent Application Publication
(10) Pub. No.: US 2020/0144374 A1
(43) Pub. Date: May 7, 2020

(54) TRANSISTOR WITH WIDE BANDGAP CHANNEL AND NARROW BANDGAP SOURCE/DRAIN

(71) Applicant: Intel Corporation, Santa Clara, CA (US)

(72) Inventors: Sean T. MA, Portland, OR (US); Cory E. WEBER, Hillsboro, OR (US); Dipanjan BASU, Hillsboro, OR (US); Harold W. KENNEL, Portland, OR (US); Willy RACHMADY, Beaverton, OR (US); Gilbert DEWEY, Hillsboro, OR (US); Jack T. KAVALIEROS, Portland, OR (US); Anand S. MURTHY, Portland, OR (US); Tahir GHANI, Portland, OR (US); Matthew V. METZ, Portland, OR (US); Cheng-ying HUANG, Hillsboro, OR (US)

(21) Appl. No.: 16/612,303

(22) PCT Filed: Jun. 30, 2017
(86) PCT No.: PCT/US2017/040285

§ 371 Date: Nov. 8, 2019

(51) Int. Cl. H01L 29/205; H01L 29/78; H01L 29/66

(52) U.S. Cl. CPC H01L 29/205; H01L 29/66462; H01L 29/785

(57) ABSTRACT

An electronic device comprises a first layer on a buffer layer on a substrate. A source/drain region is deposited on the buffer layer. The first layer comprises a first semiconductor. The source/drain region comprises a second semiconductor. The second semiconductor has a bandgap that is smaller than a bandgap of the first semiconductor. A gate electrode is deposited on the first layer.

### FIELD

Embodiments as described herein generally relate to a field of electronic device manufacturing, and in particular, to manufacturing III-V material based electronic devices.

### BACKGROUND

Generally, III-V materials have higher electron mobility relative to conventional silicon. III-V materials can be used for high performance electronic devices in integrated circuit manufacturing. The III-V material based devices may be used for system-on-chips (“SoCs”) applications, for example, for power management integrated circuits (“ICs”) and radio frequency (“RF”)-power amplifiers. The III-V material based transistors may be used for high voltage and high frequency applications.

Typically, fin-based transistors are fabricated to improve electrostatic control over the channel, reduce the leakage current and overcome other short-channel effects comparing with planar transistors.

A conventional technique to fabricate a III-V transistor involves growing a narrow bandgap InGaAs channel layer on a wide bandgap GaAs buffer layer in trenches in silicon dioxide on a silicon substrate using an aspect ratio trapping (ART) technique. Generally, the ART refers to a technique that causes the defects to terminate at the silicon dioxide sidewalls of the trenches. The wide bandgap GaAs buffer layer is used to prevent parasitic leakage from a source to a drain of the transistor.

Currently, III-V material based field effect transistors (FETs) suffer from an off-state leakage associated with narrow bandgap semiconductor channel materials due to elevated band-to-band tunneling (BTBT), BTBT induced barrier lowering (BIBL), or both BTBT and BIBL comparing to conventional silicon transistors. The off-state leakage degrades the performance of the III-V transistors. For example, the off-state leakage degrades the ability of the device to completely turn off.

### BRIEF DESCRIPTION OF THE DRAWINGS

Embodiments of the invention may be best understood by referring to the following description and accompanying drawings that are used to illustrate embodiments of the invention. In the drawings:

FIG. 1 is a view illustrating an electronic device structure according to one embodiment.

FIG. 2 is a view similar to FIG. 1 after a buffer layer is deposited according to one embodiment.

FIG. 3 is a view similar to FIG. 2 after a semiconductor channel layer is deposited on the buffer layer and the insulating layer is recessed to form a fin 301 according to one embodiment.

FIG. 4 is a view similar to FIG. 3 after a gate electrode is deposited on a channel portion of the semiconductor channel layer according to one embodiment.

FIG. 5 is a perspective view illustrating the electronic device structure depicted in FIG. 4 according to one embodiment.

FIG. 6 is a view similar to FIG. 4, after portions of the semiconductor channel layer are removed according to one embodiment.

FIG. 7 is a view similar to FIG. 6, after source/drain regions are formed according to one embodiment.

FIG. 8 is a perspective view illustrating the electronic device structure according to one embodiment.

FIG. 9 is a view similar to FIG. 7, after a metal gate stack is deposited on a gate dielectric on the wide bandgap semiconductor channel layer and contacts are formed on source/drain regions according to one embodiment.

FIG. 10 is a view illustrating an electronic device structure according to one embodiment.

FIG. 11 is a view illustrating an energy band diagram of the electronic device structure according to one embodiment.

FIG. 12 is a view of a graph including a set of curves showing an off-state leakage drain current Id of a narrow bandgap transistor as a function of a gate voltage Vg at different drain voltages according to one embodiment.

FIG. 13 is a view illustrating an energy band diagram of the electronic device structure according to one embodiment.

FIG. 14 is a view of a graph including a set of curves showing an off-state leakage drain current Id of a wide bandgap transistor having the narrow bandgap source/drain regions as a function of a gate voltage Vg at different drain voltages according to one embodiment.

FIG. 15 illustrates an interposer that includes one or more embodiments of the invention.

FIG. 16 illustrates a computing device in accordance with one embodiment of the invention.

### DETAILED DESCRIPTION

Methods and apparatuses to reduce a BTBT induced leakage in field effect transistors are described. In one embodiment, an electronic device comprises a semiconductor channel layer on a buffer layer on a substrate. A source/drain region is deposited on the buffer layer. The source/drain region comprises a semiconductor that has a bandgap smaller than a bandgap of the semiconductor channel layer. A gate electrode is deposited on the semiconductor channel layer. In one embodiment, the semiconductor of the channel layer has a conduction band that has a substantially zero offset relative to the conduction band of the source/drain region.

Embodiments of the electronic device including the semiconductor source/drain region that has a bandgap smaller than a bandgap of the semiconductor channel layer significantly reduce elevated off-state leakage current caused by the band-to-band tunneling (BTBT), the BTBT induced floating body barrier lowering (BIBL), or both the BTBT and BIBL comparing to conventional devices.

Typically, a field effect transistor has a narrow bandgap channel and wide bandgap semiconductor source/drain regions that have a bandgap greater than that of the channel Typically, for the conventional field effect transistor to reduce BTBT a large gate-to-source/drain overlap is needed to contain the high electrical field region by the wide bandgap material of the source/drain. This limits the scalability of the transistor device gate length when the gate length scaling approaches about the size that is about the size of the two times the overlap. Typically, the field effect transistor has a large VBO between the wide bandgap source/drain and the narrow bandgap channel. This large VBO raises the well energy of the body of the transistor and causes holes created by BTBT to float inside the well. This phenomenon is called a BTBT induced barrier lowering (BIBL). The BIBL reduces the barrier for an electron flow at the source side that results in an elevated thermionic leakage.

Embodiments of the electronic device including the wide bandgap channel region and the narrow bandgap source/drain region that has a bandgap smaller than that of the channel region do not require any gate-to-source/drain overlap, thus providing continued gate length scaling. In one embodiment, the electronic device includes a semiconductor channel layer that has a smaller transport mass and higher ballistic velocity of the electrical current carriers and a greater bandgap comparing to the conventional devices. Typically, the electrical current carriers refer to electrons, holes, or both electrons and holes that provide an electrical current in the semiconductor materials. In one embodiment, the electronic device includes a narrow bandgap source/drain region that has a bandgap that is smaller than the bandgap of the wide bandgap channel region to form a heterojunction between the wide bandgap channel region and narrow bandgap source/drain region. In one embodiment, the narrow bandgap source/drain region of the electronic device has an injection velocity of the carriers greater than that of the conventional devices. The narrow bandgap source/drain region of the electronic device has a conduction band offset (CBO) relative to the wide bandgap channel region that is substantially small, e.g., less than 0.1 eV. The narrow bandgap source/drain region of the electronic device has a valence band offset (VBO) relative to the wide bandgap channel region that is substantially larger than that of in the conventional devices. In one embodiment, the VBO of the narrow bandgap source/drain region relative to the wide bandgap channel region of the electronic device is at least 0.4 electron volts (eV). In one embodiment, the wide bandgap channel region has the reduced transport mass and increased ballistic velocity of the carriers to increase drive performance of the electronic device comparing to the conventional devices. In one embodiment, the wide bandgap channel region having the bandgap that is greater than the bandgap of the source/drain region reduces the BTBT of the electronic device comparing to conventional devices. In one embodiment, the narrow bandgap source/drain region having the increased injection velocity of the carriers and small CBO relative to the wide bandgap channel region reduces external resistance (Rext) of the electronic device comparing to conventional devices. In one embodiment, the narrow bandgap source/drain region having the substantially large VBO relative to the wide bandgap channel region reduces the BIBL leakage current comparing to conventional devices.

In the following description, various aspects of the illustrative implementations will be described using terms commonly employed by those skilled in the art to convey the substance of their work to others skilled in the art. However, it will be apparent to those skilled in the art that the embodiments of the present invention may be practiced with only some of the described aspects. For purposes of explanation, specific numbers, materials and configurations are set forth in order to provide a thorough understanding of the illustrative implementations. However, it will be apparent to one skilled in the art that the embodiments of the present invention may be practiced without specific details. In other instances, well-known features are omitted or simplified in order not to obscure the illustrative implementations.

Various operations will be described as multiple discrete operations, in turn, in a manner that is most helpful in understanding the embodiments of the present invention; however, the order of description should not be construed to imply that these operations are necessarily order dependent. In particular, these operations need not be performed in the order of presentation.

While certain exemplary embodiments are described and shown in the accompanying drawings, it is to be understood that such embodiments are merely illustrative and not restrictive, and that the embodiments are not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in at least one embodiment. Thus, the appearance of the phrases, such as “one embodiment” and “an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. Thus, the claims following the Detailed Description are hereby expressly incorporated into this Detailed Description, with each claim standing on its own as a separate embodiment. While the exemplary embodiments have been described herein, those skilled in the art will recognize that these exemplary embodiments can be practiced with modification and alteration as described herein. The description is thus to be regarded as illustrative rather than limiting.

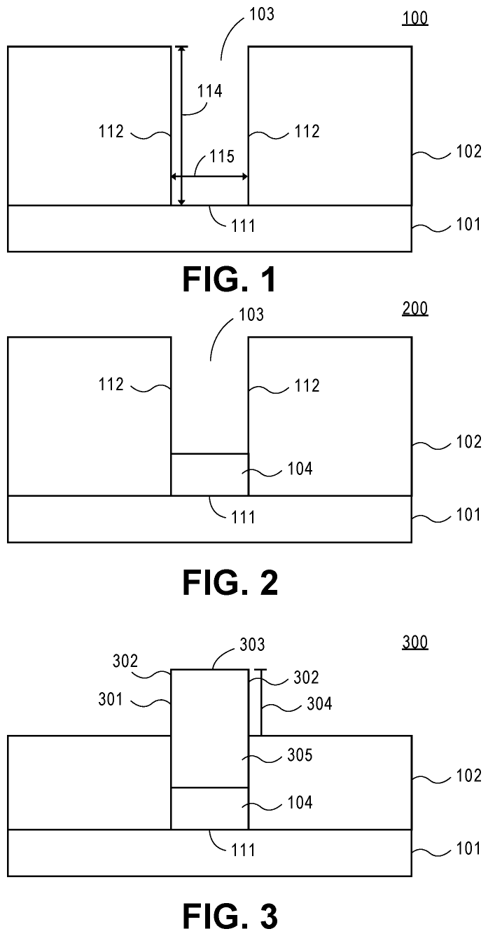

FIG. 1 is a view 100 illustrating an electronic device structure according to one embodiment. An insulating layer 102 is deposited on a substrate 101, as shown in FIG. 1. A trench 103 is formed in the insulating layer 102. In at least some embodiments, trench 103 represents one of a plurality of trenches that are formed on substrate 101. As shown in FIG. 1, trench 103 has a bottom 111 that is an exposed portion of the substrate 101 and opposing sidewalls 112. In one embodiment, the bottom portion 111 of the trench 103 has slanted sidewalls that meet at an angle (not shown).

In an embodiment, the bottom portion 111 is formed by etching the exposed portion of the substrate 101 aligned along a (100) crystallographic plane (e.g., Si (100)). In one embodiment, the etch process etches the portions of the substrate aligned along a (100) crystallographic plane (e.g., Si (100)) fast and slows down at the portions of the substrate aligned along (111) crystallographic planes (e.g., Si (111)). In one embodiment, the etch process stops when the portions of Si (111) are met that results in a V-shaped bottom portion 111.

Trench 103 has a depth D 114 and a width W 115. In one embodiment, depth 114 is determined by the thickness of the insulating layer 102. In an embodiment, the width of the trench is determined by the width of the electronic device. In at least some embodiments, the electronic device has a fin based transistor architecture (e.g., FinFET, Trigate, GAA, a nanowire based device, a nanoribbons based device, or any other electronic device architecture). In one embodiment, the width 115 is from about 5 nanometers (nm) to about 300 nm. In an embodiment, the aspect ratio of the trench (D/W) is at least 1.5.

In an embodiment, the substrate 101 comprises a semiconductor material. In one embodiment, substrate 101 is a monocrystalline semiconductor substrate. In another embodiment, substrate 101 is a polycrystalline semiconductor substrate. In yet another embodiment, substrate 101 is an amorphous semiconductor substrate. In an embodiment, substrate 101 is a semiconductor-on-isolator (SOI) substrate including a bulk lower substrate, a middle insulation layer, and a top monocrystalline layer. The top monocrystalline layer may comprise any semiconductor material.

In various implementations, the substrate can be, e.g., an organic, a ceramic, a glass, or a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the embodiments of the present invention.

In another embodiment, substrate 101 comprises a III-V material. Generally, the III-V material refers to a compound semiconductor material that comprises at least one of group III elements of the periodic table, e.g., boron (“B”), aluminum (“Al”), gallium (“Ga”), indium (“In”), and at least one of group V elements of the periodic table, e.g., nitrogen (“N”), phosphorus (“P”), arsenic (“As”), antimony (“Sb”), bismuth (“Bi”). In an embodiment, substrate 101 comprises InP, GaAs, InGaAs, InAlAs, other III-V material, or any combination thereof.

In alternative embodiments, substrate 101 includes a group IV material layer. Generally, the group IV material refers to a semiconductor material comprising one or more elements of the group IV of the periodic table, e.g., carbon (C), silicon (Si), germanium (Ge), tin (Sn), lead (Pb), or any combination thereof. In one embodiment, substrate 101 comprises a silicon layer, a germanium layer, a silicon germanium (SiGe) layer, or any combination thereof.

In one embodiment, substrate 101 includes one or more metallization interconnect layers for integrated circuits. In at least some embodiments, the substrate 101 includes interconnects, for example, vias, configured to connect the metallization layers. In at least some embodiments, the substrate 101 includes electronic devices, e.g., transistors, memories, capacitors, resistors, optoelectronic devices, switches, and any other active and passive electronic devices that are separated by an electrically insulating layer, for example, an interlayer dielectric, a trench insulation layer, or any other insulating layer known to one of ordinary skill in the art of the electronic device manufacturing. In one embodiment, the substrate includes one or more buffer layers to accommodate for a lattice mismatch between the substrate 101 and one or more layers above substrate 101 and to confine lattice dislocations and defects.

Insulating layer 102 can be any material suitable to insulate adjacent devices and prevent leakage. In one embodiment, electrically insulating layer 102 is an oxide layer, e.g., silicon dioxide, or any other electrically insulating layer determined by an electronic device design. In one embodiment, insulating layer 102 comprises an interlayer dielectric (ILD). In one embodiment, insulating layer 102 is a low-k dielectric that includes, but is not limited to, materials such as, e.g., silicon dioxide, silicon oxide, carbon doped oxide (“CDO”), e.g., carbon doped silicon dioxide, porous silicon dioxide, silicon nitride, or any combination thereof. In one embodiment, insulating layer 102 includes a dielectric material having k-value less than 5. In one embodiment, insulating layer 102 includes a dielectric material having k-value less than 2. In at least some embodiments, insulating layer 102 includes a nitride, oxide, a polymer, phosphosilicate glass, fluorosilicate (SiOF) glass, organosilicate glass (SiOCH), other electrically insulating layer determined by an electronic device design, or any combination thereof. In one embodiment, insulating layer 102 is a shallow trench isolation (STI) layer to provide field isolation regions that isolate one fin from other fins on substrate 101. In one embodiment, the thickness of the insulating layer 102 is at least 10 nm. In one non-limiting example, the thickness of the insulating layer 102 is in an approximate range from about 10 nm to about 2 microns (μm).

In an embodiment, the insulating layer is deposited on the substrate using one or more of the deposition techniques, such as but not limited to a chemical vapour deposition (“CVD”), a physical vapour deposition (“PVD”), molecular beam epitaxy (“MBE”), metalorganic chemical vapor deposition (“MOCVD”), atomic layer deposition (“ALD”), spin-on, or other insulating deposition techniques known to one of ordinary skill in the art of microelectronic device manufacturing. In one embodiment, trench 103 is formed in the insulating layer 102 using one or more patterning and etching techniques known to one of ordinary skill in the art of microelectronic device manufacturing.

FIG. 2 is a view 200 similar to FIG. 1 after a buffer layer 104 is deposited onto the bottom 111 between sidewalls 112 and 113 of the trench 103 according to one embodiment. The buffer layer 104 is deposited to accommodate for a lattice mismatch between the substrate 101 and one or more layers above the buffer layer 104 and to confine lattice dislocations and defects.

In an embodiment, buffer layer 104 has a lattice parameter between the lattice parameter of the substrate 101 and a semiconductor layer which is formed thereon. Generally, a lattice constant is a lattice parameter that is typically referred to as a distance between unit cells in a crystal lattice. Lattice parameter is a measure of the structural compatibility between different materials. In one embodiment, the buffer layer 104 has a graded bandgap that gradually changes from the interface with the substrate 101 to the interface with a semiconductor layer. In various embodiments the buffer layer 104 may have different numbers of layers or simply be a single layer.

In one embodiment, an aspect ratio D/W of the trench 103 determines the thickness of the buffer layer 104. In an embodiment, the thickness of the buffer layer 104 is such that most defects originated from the lattice mismatch are trapped within the buffer layer and are prevented from being propagated into a device semiconductor layer above the buffer layer 104 using an aspect ratio trapping (ART).

In one embodiment, buffer layer 104 has the sufficient thickness that most defects present at the bottom 111 do not reach the top surface of the buffer layer 104. In one embodiment, the thickness of the buffer layer 104 is at least about 5 nm. In one embodiment, the thickness of the buffer layer 104 is from about 5 nm to about 500 nm.

In one embodiment, the buffer layer 104 comprises a III-V material. In an embodiment, substrate 101 is a silicon substrate, and buffer layer 104 comprises a III-V material, e.g., InP, GaAs, InGaAs, InAs, InAlAs, other III-V material, or any combination thereof. In another embodiment, buffer layer 104 comprises a group IV material. In one embodiment, buffer layer 104 comprises Si, Ge, SiGe, carbon, other group IV semiconductor material, or any combination thereof. In at least some embodiments, buffer layer 104 is deposited through trench 103 onto the bottom 111 using one of epitaxial techniques known to one of ordinary skill in the art of microelectronic device manufacturing, such as but not limited to a CVD, a PVD, an MBE, an MOCVD, an ALD, spin-on, or other epitaxial growth technique.

FIG. 3 is a view 300 similar to FIG. 2 after a semiconductor channel layer 305 is deposited on buffer layer 104 and the insulating layer 102 is recessed to form a fin 301 according to one embodiment. In one embodiment, semiconductor channel layer 305 is a wide bandgap III-V material layer, such as but not limited to gallium arsenide (GaAs), indium phosphide (InP), gallium phosphide (GaP), gallium arsenide (GaAs), indium gallium phosphide (InGaP), aluminum gallium arsenide (AlₓGa₁₋ₓAs), gallium arsenide antimonide (GaAsₓSb₁₋ₓ) (where 0≤x≤1), indium gallium arsenide antimonide (InₓGa₁₋ₓAs_{y}Sb_{1-y}), indium gallium arsenide phosphide (InₓGa₁₋ₓAs_{y}P_{1-y}), indium gallium arsenide phosphide antimonide InₓGa₁₋ₓP_{y}Sb_{1-y} (where 0≤x≤0.3, 0≤y≤1), indium aluminum arsenide antimonide InₓAl₁₋ₓAs_{y}Sb_{1-y}, indium aluminum arsenide phosphide (InₓAl₁₋ₓAs_{y}P_{1-y}) (where 0.8≤x≤1, 0≤y≤1) or any combination thereof. In one embodiment, semiconductor channel layer 305 is InP, buffer layer 104 is GaAs, and substrate 101 is silicon.

In one embodiment, semiconductor channel layer 305 is a part of a channel of a transistor, as described in further detail below. In one embodiment, semiconductor channel layer 305 comprises an intentionally undoped semiconductor material. In one embodiment, semiconductor channel layer 305 has a dopant concentration equal or smaller than 10\hat{ }16 atoms/cm\hat{ }3. In one embodiment, the concentration of dopants in the semiconductor channel layer 305 is from about 10′14 atoms/cm\hat{ }3 to about 10\hat{ }16 atoms/cm\hat{ }3.

In one embodiment, the thickness of semiconductor channel layer 305 is determined by design. In one embodiment, semiconductor channel layer 305 is a part of an electronic device, e.g., a FinFET, Trigate, gate all around (GAA), a nanowire based device, a nanoribbons based device, or any other electronic device. In one embodiment, the thickness of the semiconductor channel layer 305 is at least about 5 nm. In one embodiment, the thickness of the semiconductor channel layer 305 is from about 5 nm to about 500 nm.

In one embodiment, semiconductor channel layer 305 is deposited on the buffer layer 104 in the trench 103 and on top of the insulating layer 102. In an embodiment, semiconductor channel layer 305 is deposited using one of deposition techniques, such as but not limited to a CVD, a PVD, an MBE, an MOCVD, an ALD, spin-on, or other deposition techniques known to one of ordinary skill in the art of microelectronic device manufacturing.

The semiconductor channel layer 305 is then polished back to be planar with the top portions of the insulating layer 102 using a chemical mechanical polishing (CMP) process as known to one of ordinary skill in the art of microelectronic device manufacturing. The insulating layer 102 is then recessed down to a predetermined depth that defines a height 304 of the fin 301. In one embodiment, a patterned hard mask (not shown) is deposited onto semiconductor channel layer 305 before recessing insulating layer 102. In one embodiment, insulating layer 102 is recessed by an etching technique, such as but not limited to a wet etching, a dry etching, or any combination thereof techniques using a chemistry that has substantially high selectivity to the semiconductor channel layer 305. In one embodiment, after recessing the insulating layer 102, the patterned hard mask is removed by a chemical mechanical polishing (CMP) process as known to one of ordinary skill in the art of microelectronic device manufacturing.

As shown in FIG. 3, fin 301 is a portion of the semiconductor channel layer 305 that protrudes from a top surface of the insulating layer 102. Fin 301 comprises a top portion 303 and opposing sidewalls 302. In an embodiment, the length of the fin is substantially greater than the width. The height and the width of the fin 301 are typically determined by a design. In one embodiment, the width of the fin 301 is determined by the width 115 of the trench 103. In an embodiment, the height of the fin 301 is from about 10 nm to about 100 nm and the width of the fin 301 is from about 5 nm to about 20 nm.

In another embodiment, forming the fin 301 involves depositing the semiconductor channel layer 305 on the buffer layer 104 on the substrate 101 using one or more of deposition techniques, such as but not limited to a CVD, a PVD, an MBE, an MOCVD, an ALD, spin-on, or other deposition techniques known to one of ordinary skill in the art of microelectronic device manufacturing. A stack comprising the semiconductor channel layer 305 on the buffer layer 104 is patterned and etched using one or more fin patterning and etching techniques known to one of ordinary skill in the art of microelectronic device manufacturing to form the fin 301. The insulating layer 102 is deposited to a predetermined thickness adjacent to portions of the sidewalls of the fin stack on the substrate.

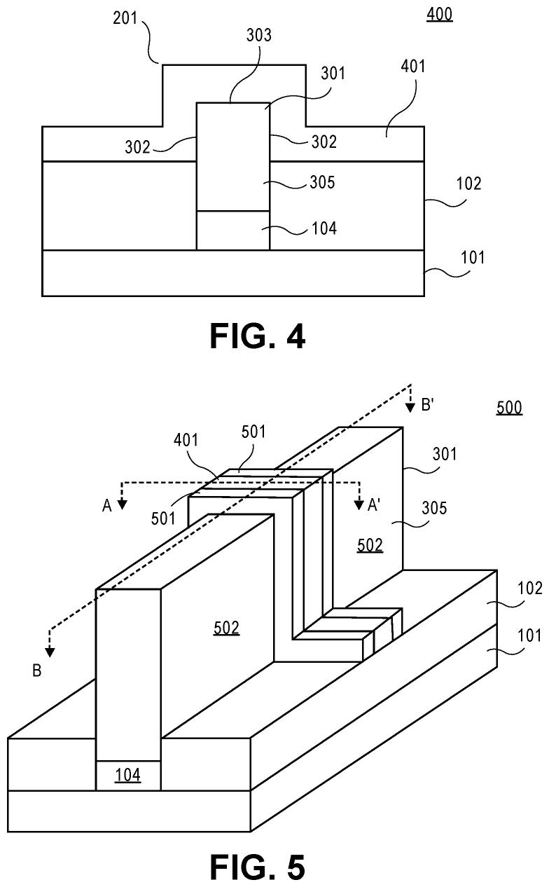

FIG. 4 is a view 400 similar to FIG. 3 after a gate electrode 401 is deposited on a channel portion of the semiconductor channel layer 305 according to one embodiment. FIG. 5 is a perspective view 500 illustrating the electronic device structure depicted in FIG. 4 according to one embodiment. In one embodiment, the electronic device structure depicted in FIGS. 5 and 4 is a transistor structure. View 400 is a cross-sectional view of the electronic device structure shown in FIG. 5 along an axis A-A′ (“gate cut view”) according to one embodiment. As shown in FIG. 5, an axis B-B′ represents a source-drain cut view.

As shown in FIGS. 4 and 5, gate electrode 401 is deposited on and around the fin 301. Gate electrode 401 is deposited on top portion 303 and opposing sidewalls 302 of a portion of the fin 301. In one embodiment, the area of the fin 301 surrounded by the gate electrode 401 defines a channel portion of the transistor device. In one embodiment, the gate electrode 401 is a sacrificial (dummy) gate electrode.

Gate electrode 401 can be formed of any suitable gate electrode material, such as but not limited to a polysilicon, a metal, or any combination thereof. In at least some embodiments, the gate electrode 401 is deposited using one or more of the gate electrode deposition and patterning techniques known to one of ordinary skill in the art of microelectronic device manufacturing.

In one embodiment, a dummy gate electrode stack comprising a dummy gate electrode on a dummy gate dielectric (not shown) is formed on the channel portion of the fin 301. Example dummy gate dielectric materials include silicon dioxide, although any suitable dummy gate dielectric material can be used.

As shown in FIG. 5, spacers 501 are formed on the opposite sidewalls of the gate electrode 401. In one embodiment, the thickness of the spacers 501 is from 1 nm to about 10 nm, or other thickness determined by design to target the tradeoffs between large S/D contact area (which requires a thin spacer) and small contact-to-gate parasitic capacitance (which requires a thick spacer). In one embodiment, the portions 502 of the fin 301 exposed by the spacers 501 at opposite sides of the gate electrode 401 define source/drain regions of the transistor device.

In at least some embodiments, spacers 501 are formed using one or more spacer deposition techniques known to one of ordinary skill in the art of the microelectronic device manufacturing. In one embodiment, the spacers 501 are low-k dielectric spacers. In one embodiment, the spacers 501 are nitride spacers (e.g., silicon nitride), oxide spacers, carbide spacers (e.g., silicon carbide), or other spacers.

As shown in FIGS. 4 and 5, the electronic device has gate electrode 401 surrounding the fin 301 on three sides that provides three channels on the fin 301, one channel extends between the source and drain regions on one of the sidewalls 302 of the fin 301, a second channel extends between the source and drain regions on the top portion 303 of the fin 301, and the third channel extends between the source and drain regions on the other one of the sidewalls 302 of the fin 301. As shown in FIGS. 4 and 5, gate electrode 401 has a top portion and laterally opposite sidewalls separated by a distance that defines the length of the channel on the fin 301. In one embodiment, the length of the channel on the fin 301 is from about 5 nanometers (nm) to about 300 nm. In one embodiment, the length of the channel on the fin 301 is from about 10 nm to about 20 nm.

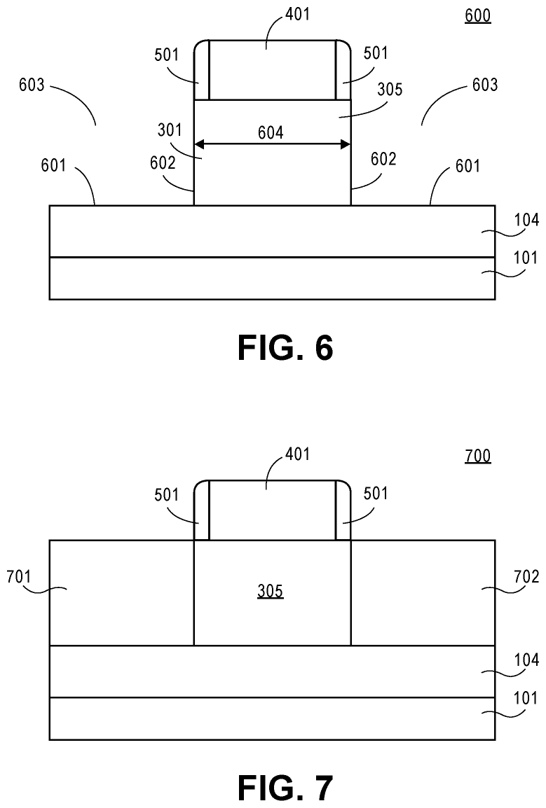

FIG. 6 is a view 600 similar to FIG. 4, after portions 502 of the semiconductor channel layer 305 are removed according to one embodiment. View 600 is a cross-sectional view of the electronic device structure shown in FIG. 5 along axis B-B′, after portions 502 are removed. As shown in FIG. 6, portions 502 of the semiconductor channel layer 105 are removed to form recesses 603. As shown in FIG. 6, each of the recesses 603 is defined by the exposed portion 601 of the buffer layer 104 and the sidewall 602 of the semiconductor channel layer 305 underneath the edge of the spacer 501. As shown in FIG. 6, the remaining semiconductor channel layer 305 has a width 604 that is defined by the width of the gate electrode 401 and the thickness of the spacers 501.

In one embodiment, recesses 603 are formed by etching portions 502 of the semiconductor channel layer 305 outside the gate electrode 401 and spacers 501. In one embodiment, gate electrode 401 and spacers 501 are used as a mask to selectively remove portions 502 of the semiconductor channel layer 305. In one embodiment, portions 502 are selectively removed using one of the dry etching techniques known to one of ordinary skill in the art of the microelectronic device manufacturing.

FIG. 7 is a view 700 similar to FIG. 6, after source/drain regions 701 and 702 are formed in recesses 603 according to one embodiment. In one embodiment, the source/drain regions 701 and 702 comprise a narrow bandgap semiconductor that has a bandgap smaller than a bandgap of the semiconductor channel layer 305. In one embodiment, each of the source/drain regions 701 and 702 is a narrow bandgap III-V material layer, such as but not limited to indium gallium arsenide (InGaAs), indium arsenide (InAs), indium antimonide (InSb), indium gallium antimonide (InGaSb), other narrow bandgap III-V material, indium gallium arsenide antimonide (InₓGa₁₋ₓAs_{y}Sb_{1-y}), indium gallium arsenide phosphide (InₓGa₁₋ₓAs_{y}P_{1-y}), indium gallium phosphide antimonide (InₓGa₁₋ₓP_{y}Sb_{1-y}), indium aluminum arsenide antimonide (InₓAl₁₋ₓAs_{y}Sb_{1-y}), indium aluminum arsenide phosphide (InₓAl₁₋ₓAs_{y}P_{1-y}), where 0≤x≤1, 0≤y≤1, or any combination thereof.

In one embodiment, each of the source/drain regions 701 and 702 is InGaAs, buffer layer 104 is GaAs, and substrate 101 is silicon. In more specific embodiment, each of the source/drain regions 701 and 702 is an Inₓ Ga₁₋ₓ As layer, where x is in an approximate range from about 0.3 to about 0.7. In one specific embodiment, the material of the semiconductor channel layer 305 is InP and the material of the source/drain regions 701 and 702 is InGaAs. In one embodiment, the wide bandgap semiconductor channel layer 305 has a conduction band that has a zero offset relative to the conduction band of the narrow bandgap semiconductor source/drain regions 701 and 702. In one embodiment, a valence band of the wide bandgap semiconductor channel layer 305 is offset relative to a valence band of the narrow bandgap semiconductor source/drain region by at least 0.4 eV.

In at least some embodiments, the source/drain regions 701 and 702 are formed of the same conductivity type such as N-type or P-type conductivity. In another embodiment, the source and drain regions 701 and 702 are doped of opposite type conductivity. In one embodiment, the dopant concentration in the narrow bandgap source/drain regions 701 and 702 is substantially greater than in the wide bandgap semiconductor channel layer 305. In an embodiment, the channel portion of the fin including wide bandgap semiconductor channel layer 305 is intrinsic or undoped. In one embodiment, the source/drain regions 701 and 702 have a dopant concentration of at least 1×10\hat{ }19 atoms/cm\hat{ }3. In one embodiment, the concentration of the dopants in the source/drain regions 701 and 702 is from about 10\hat{ }18 atoms/cm\hat{ }3 to about 10\hat{ }22 atoms/cm\hat{ }3.

In an embodiment, the channel portion of the fin including wide bandgap semiconductor channel layer 305 is doped, for example to a conductivity level of equal or smaller than 1×10\hat{ }16 atoms/cm\hat{ }3. In an embodiment, when the channel portion is doped it is typically doped to the opposite conductivity type of the source/drain portion. For example, when the source/drain regions are N-type conductivity the channel portion would be doped to a P-type conductivity. Similarly, when the source/drain regions are P-type conductivity the channel portion would be N-type conductivity. In this manner a fin based transistor can be formed into either a NMOS transistor or a PMOS transistor respectively. The channel portion can be uniformly doped or can be doped non-uniformly or with differing concentrations to provide particular electrical and performance characteristics. For example, channel portion can include halo regions, if desired. The narrow bandgap source/drain regions 701 and 702 can be formed of uniform concentration or can include sub-regions of different concentrations or doping profiles such as tip regions (e.g., source/drain extensions). In an embodiment, the source/drain regions 701 and 702 have the same doping concentration and profile. In an embodiment, the doping concentration and profile of the source/drain regions 701 and 702 vary to obtain a particular electrical characteristic. In at least some embodiments, the wide bandgap source/drain regions 701 and 702 are deposited into recesses 603 using one or more of deposition techniques known to one of ordinary skill in the art of microelectronic device manufacturing, such as but not limited to a CVD, a PVD, an MBE, an MOCVD, an ALD, spin-on, or other deposition technique.

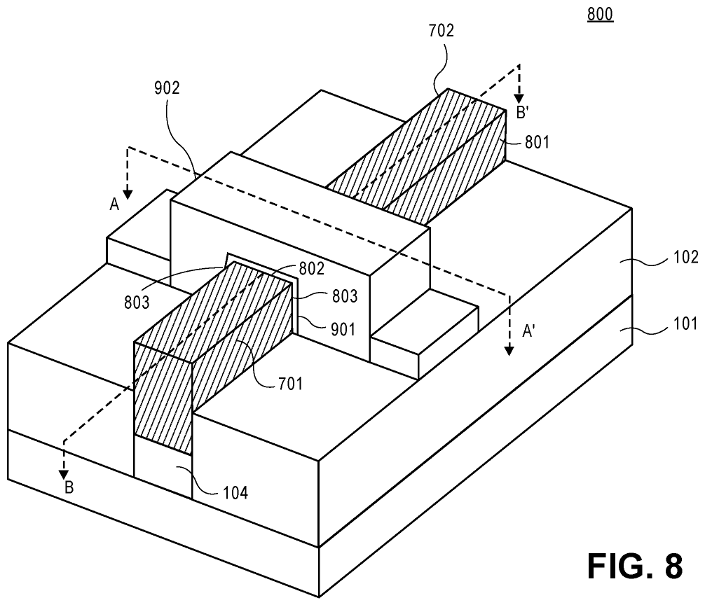

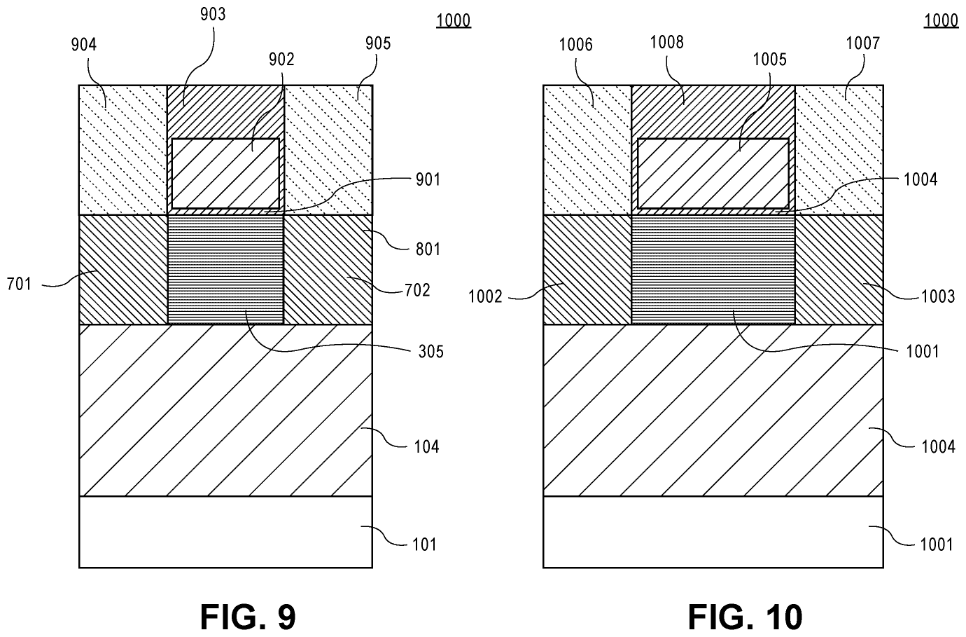

FIG. 8 is a perspective view 800 illustrating the electronic device structure according to one embodiment. FIG. 9 is a view 900 similar to FIG. 7, after a metal gate stack 902 is deposited on a gate dielectric 901 on the wide bandgap semiconductor channel layer 305 and contacts 904 and 905 are formed on source/drain regions 701 and 702 according to one embodiment. Perspective view 800 represents a portion of the electronic device structure depicted in FIG. 9 without contacts 904 and 905 and a capping insulating layer 903. FIG. 9 represents a cross-sectional view of a portion of the electronic device structure depicted in FIG. 8 along an axis B-B′ (source-drain cut view) according to one embodiment. As shown in FIG. 8, an axis A-A′ represents a gate cut view.

As shown in FIGS. 8 and 9, gate electrode 401 is removed and replaced with the metal gate stack 902 on the gate dielectric 901. In one embodiment, a protection layer (not shown), e.g., a nitride etch stop layer (NESL) is deposited on source/drain regions 701 and 702 to selectively remove sacrificial gate electrode 401. In one embodiment, gate electrode 401 is removed to form a trench having exposed semiconductor channel layer 305 and portions as a bottom and spacers 501 as opposing sidewalls. The dummy gate electrode can be removed using one or more of the dummy gate electrode removal techniques known to one of ordinary skill in the art of electronic device manufacturing.

As shown in FIGS. 8 and 9, gate dielectric 901 is deposited on the exposed portions of the semiconductor channel layer 305. In one embodiment, the gate dielectric 901 wraps around the wide bandgap channel layer 305. In one embodiment, gate dielectric 901 is an oxide layer, e.g., a silicon oxide layer, an aluminum oxide, a hafnium containing oxide, or any combination thereof. In one embodiment, the gate dielectric 901 is a high-k dielectric material, for example, hafnium oxide, hafnium silicon oxide, hafnium zirconium oxide (HfxZryOz), lanthanum oxide (La2O3), lanthanum aluminum oxide, zirconium oxide, zirconium silicon oxide, tantalum oxide, tantalum silicate (TaSiOx), titanium oxide, barium strontium titanium oxide, barium titanium oxide, strontium titanium oxide, yttrium oxide, aluminum oxide (e.g., Al2O3), lead scandium tantalum oxide, and lead zinc niobate, or other high-k dielectric materials. In one embodiment, the thickness of the gate dielectric 901 is from about 2 angstroms (Å) to about 20 Å.

In an embodiment, the gate dielectric 901 is deposited using one or more of the deposition techniques, such as but not limited to a CVD, a PVD, an MBE, an MOCVD, an ALD, spin-on, or other gate dielectric deposition technique. In one embodiment, the metal gate stack 902 is formed on the gate dielectric 901 filling the trench between the spacers. In one embodiment, the metal gate stack 902 is a metal gate electrode layer, such as but not limited to, tungsten, tantalum, titanium, and their nitrides. It is to be appreciated, the metal gate electrode stack need not necessarily be a single material and can be a composite stack of thin films, such as but not limited to a polycrystalline silicon/metal electrode or a metal/polycrystalline silicon electrode. The metal gate stack 902 can be deposited using one of the gate electrode layer deposition techniques, such as but not limited to a CVD, PVD, MBE, MOCVD, ALD, spin-on, electroless, electro-plating, or other deposition techniques known to one of ordinary skill in the art of microelectronic device manufacturing.

As shown in FIGS. 8 and 9, the metal gate stack 902 is deposited on and around a fin 801. The fin 801 includes wide bandgap semiconductor channel layer 305, and source/drain regions 702 and 701. The metal gate stack 902 is deposited on a top portion 802 and opposing sidewalls 802 of a portion of the fin 801 that includes semiconductor channel layer 305. In one embodiment, the area of the fin 801 surrounded by the metal gate stack 802 defines a channel portion of the transistor device.

As shown in FIG. 9, the wide bandgap semiconductor channel layer 305 is between the narrow bandgap semiconductor source/drain regions 701 and 702.

As shown in FIGS. 8 and 9, the metal gate stack 902 surrounds the fin 801 on three sides that provides three channels on the fin 801, one channel extends between the source/drain regions 701 and 702 on one of the sidewalls 803 of the fin 801, a second channel extends between the source/drain regions 701 and 702 on the top portion 802 of the fin 801, and the third channel extends between the source/drain regions 701 and 702 on the other one of the sidewalls 803 of the fin 801. As shown in FIGS. 8 and 9, metal gate stack 902 has a top portion and laterally opposite sidewalls separated by a distance that defines the length of the channel on the fin 801. In one embodiment, the length of the channel on the fin 801 is from about 5 nanometers (nm) to about 300 nm. In one embodiment, the length of the channel on the fin 801 is from about 10 nm to about 20 nm.

In one embodiment, after the metal gate stack 902 is formed, the protection layer (not shown) on source/drain regions 701 and 702 is removed using one of the protection layer etching techniques known to one of ordinary skill in the art of microelectronic device manufacturing. As shown in FIG. 9, a contact 904 is deposited on source/drain region 701 and a contact 905 is deposited on source/drain region 702.

In one embodiment, contacts 904 and 905 are metal contacts that include a metal, such as but not limited to copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, other metals, or any combination thereof. In alternative embodiments, examples of the conductive materials that may be used for the contacts are, but not limited to, metals, e.g., copper, tantalum, tungsten, ruthenium, titanium, hafnium, zirconium, aluminum, silver, tin, lead, metal alloys, metal carbides, e.g., hafnium carbide, zirconium carbide, titanium carbide, tantalum carbide, aluminum carbide, other conductive materials, or any combination thereof.

In an embodiment, the contacts are deposited using one of contact deposition techniques, such as but not limited to a CVD, PVD, MBE, MOCVD, ALD, spin-on, electroless, electro-plating, or other contact deposition techniques known to one of ordinary skill in the art of microelectronic device manufacturing. In one embodiment, metal gate stack 902 between spacers 501 is recessed back to a predetermined height, then the spacers 501 are removed and a capping insulating layer 903 is deposited on the recessed metal gate stack 902 to encapsulate the metal gate stack 902. In one embodiment, the material of the capping insulating layer 903 is represented by one or more of the insulating layer materials described above with respect to insulating layer 102.

FIG. 10 is a view 1000 illustrating an electronic device structure according to one embodiment. As shown in FIG. 10, a metal gate stack 1005 is deposited on a gate dielectric 1004 on a narrow bandgap semiconductor channel layer 1001 on a buffer layer 1004 on a substrate 1001. Contacts 1006 and 1007 are formed on source/drain regions 1002 and 1003 on buffer layer 1004 on substrate 1201. A capping insulating layer 1008 is deposited on the metal gate stack 1005 to encapsulate the metal gate stack 1005.

In one embodiment, substrate 1001 represents one of the substrates described above with respect to substrate 101. In one embodiment, buffer layer 1004 represents one of the buffer layers described above with respect to buffer layer 104. In one embodiment, the semiconductor channel layer 1001 is a narrow bandgap III-V material layer, such as but not limited to indium gallium arsenide (InGaAs), indium arsenide (InAs), indium antimonide (InSb), indium gallium antimonide (InGaSb), indium gallium arsenide antimonide (InₓGa₁₋ₓAs_{y}Sb_{1-y}), indium gallium arsenide phosphide (InₓGa₁₋ₓAs_{y}P_{1-y}), indium gallium phosphide antimonide indium aluminum arsenide antimonide (InₓAl₁₋ₓAs_{y}Sb_{1-y}), indium aluminum arsenide phosphide (InₓAl₁₋ₓAs_{y}P_{1-y}), where 0≤x≤1, 0≤y≤1, other narrow bandgap III-V material, or any combination thereof.

In one embodiment, the gate dielectric 1004 represents one of the gate dielectrics described above. In one embodiment, the metal gate stack 1005 represents one of the metal gate stacks described above. In one embodiment, the source/drain regions 1002 and 1003 a wide bandgap semiconductor source/drain regions that have a bandgap greater than a bandgap of the semiconductor channel layer 1001. In one embodiment, the source/drain regions 1001 and 1002 are III-V material source/drain regions, such as but not limited to indium phosphide (InP), gallium arsenide (GaAs), gallium phosphide (GaP), indium gallium phosphide (InGaP), AlₓGa₁₋ₓAs, GaAsₓSb₁₋ₓ (where 0≤x≤1), InₓGa₁₋ₓAs_{y}Sb_{1-y}, InₓGa₁₋ₓAs_{y}P_{1-y}, InₓGa₁₋ₓP_{y}Sb_{1-y} (where 0≤x≤0.3, 0≤y≤1), InₓAl₁₋ₓAs_{y}Sb_{1-y}, InₓAl₁₋ₓAs_{y}P_{1-y} (where 0.8≤x≤1, 0≤y≤1), or any combination thereof.

In one embodiment, the contacts 1006 and 1007 represent the contacts described above with respect to contacts 904 and 905. In one embodiment, the capping insulating layer 1008 represent one of the capping insulating layers described above with respect to the capping insulating layer 903.

FIG. 10 is different from FIG. 9 in that the narrow bandgap semiconductor material is deposited in the channel region and the wide bandgap semiconductor material is deposited in the source/drain regions 1002 and 1003. The wideband gap materials deposited in the source/drain regions are not effective in the BTBT reduction, as described in further detail below.

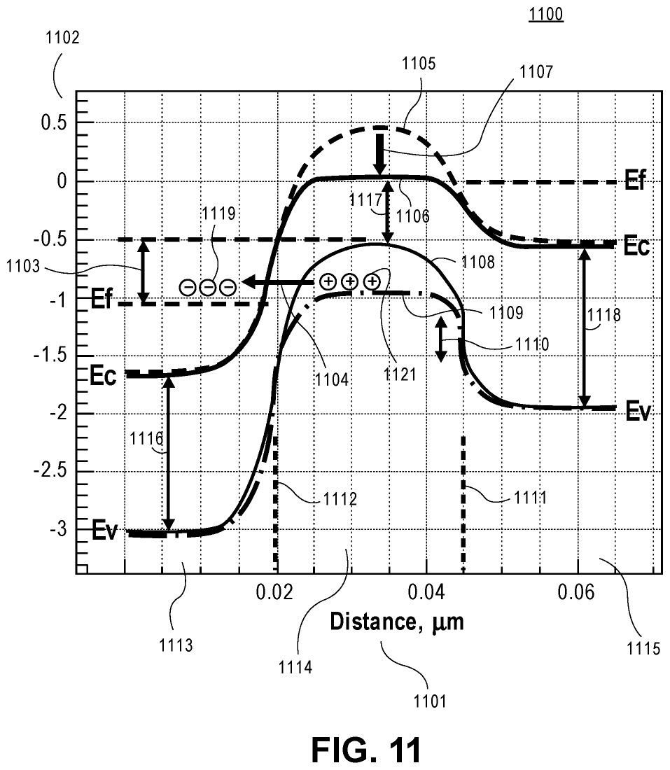

FIG. 11 is a view 1100 illustrating an energy band diagram of the electronic device structure according to one embodiment. As shown in FIG. 11, the energy band diagram includes an energy 1102 of the electric current carriers as a function of a distance 1101 along the electronic device structure. The electronic device structure includes a wide bandgap drain region 1113 adjacent to a narrow bandgap channel region 1114 adjacent to a wide bandgap source region 1115. In one embodiment, the narrow bandgap channel region 1114 represents the semiconductor channel layer 1001, and the wide bandgap drain region 1113 and wide bandgap source region 1115 represent the wide bandgap source/drain regions 1002 and 1003 depicted in FIG. 10.

The narrow bandgap channel region 1114 is beneath the gate electrode (not shown). As shown in FIG. 11, the narrow bandgap channel region 1114 is within the edges 1111 and 1112 of the gate electrode. As shown in FIG. 11, the wide bandgap drain region 1113 and the wide bandgap source region 1115 are outside of the gate electrode edges 1111 and 1112.

As shown in FIG. 11, the wide bandgap drain region 1113 has a conduction energy band E_{c} and a valence energy band Eᵥ that are separated by a bandgap Eg 1116, narrow bandgap channel region 1114 has a conduction energy band E_{c} and a valence energy band Eᵥ that are separated by a bandgap Eg, 1117 and the wide bandgap source region 1115 has a conduction energy band E_{c} and a valence energy band Eᵥ that are separated by a bandgap Eg 1118. As shown in FIG. 11, the bandgap of the wide bandgap drain region 1113 is greater than the bandgap Eg of the narrow bandgap channel region 1114. The bandgap of the wide bandgap source region 1115 is greater than the bandgap Eg of the narrow bandgap channel region 1114. As shown in FIG. 11, the valence band of the wide bandgap source region 1115 has a valence band offset VBO 1110 at the gate edge 1111 relative to the valence band of the narrow bandgap channel region 1114. Generally, the VBO is defined as a valence band discontinuity at the interface between the wide bandgap semiconductor and the narrow bandgap semiconductor. As shown in FIG. 11, at the gate edge 1111 the valence band of the channel region 1114 and the valence band of the source region 1115 bend towards each other. As shown in FIG. 11, at the gate edge 1111 the valence band of the narrow bandgap channel region 1114 is higher than the valence band of the wide bandgap source region 1115.

As shown in FIG. 11, electrons 1119 tunnel 1104 from the valence band Ev of the narrow bandgap channel region 1114 through the barrier to the conduction band Ec of the wide bandgap drain region 1113 above the Fermi level Ef leaving floating holes 1121 in the narrow bandgap channel region 1114. As shown in FIG. 11, electron tunneling 1104 occurs within a BTBT window 1103. As shown in FIG. 11, the BTBT increases a floating charge (holes) that lowers an energy of the valence band Ev in the narrow bandgap region 1114 from an energy 1108 to an energy 1109. Generally, the BTBT window is defined as a distance between the valence band Ev in the narrow bandgap semiconductor and the Fermi level Ef in the wide bandgap semiconductor. The electron tunneling from the narrow bandgap channel region 1114 to the wide bandgap drain region 1113 within the BTBT window 1103 increases the off-state leakage current Id. As shown in FIG. 11, the valence band offset VBO 1110 is outside the BTBT window 1103. The VBO 1110 raises the barrier for the BTBT induced holes, as shown in FIG. 11.

As shown in FIG. 11, the BTBT reduces an energy barrier from a conduction band level 1105 to a conduction band level 1106 for thermal electrons that travel from the wide bandgap region 1115 to the narrow bandgap channel region 1114 above the Fermi level. The BTBT induced barrier lowering (BIBL) 1107 further increases the off-state leakage current Id.

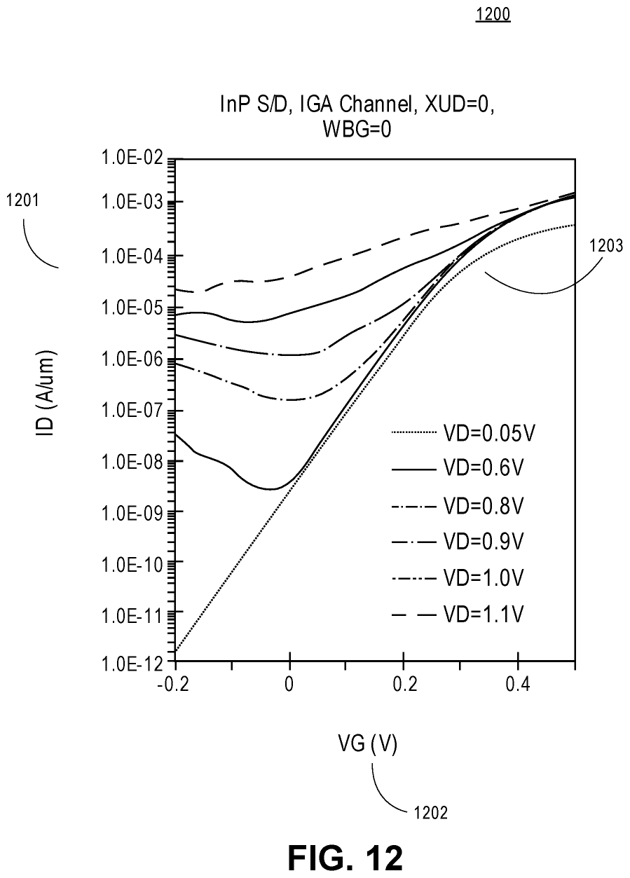

FIG. 12 is a view 1200 of a graph including a set of curves 1203 showing an off-state leakage drain current Id 1201 of a narrow bandgap transistor as a function of a gate voltage Vg 1202 at different drain voltages according to one embodiment. In one embodiment, the narrow bandgap transistor has a structure that is similar to the narrow bandgap electronic device structure depicted in FIG. 10. In one embodiment, the transistor has InP source/drain regions, InGaAs channel region, gate-to-source/drain overlap (XUD) is zero where the heterojunctions of InP source/drain and InGaAs channel are at the gate edges (XUD=0). As shown in FIG. 12, when the narrow bandgap transistor is turned off (voltage at the gate electrode Vg is zero), the gate induced drain leakage (GIDL) Id increases as the bias voltage between the source and drain Vd increases. Typically, for the conventional narrow bandgap transistor devices, the off-state GIDL Id is elevated due to the BTBT or a combination of the BTBT and BIBL. In the latter case, the BTBT induced charge in the channel cannot easily flow into the substrate electrode, but floats inside the channel and the GIDL Id is due to both the BTBT and BIBL. Typically, the BTBT induced charge floats in the channel because there is no substrate or because there is an energy barrier which the BTBT induced charge cannot overcome. The type of devices in which the floating charge can occur include silicon on insulator (SOI) devices, gate-all-around devices, nanowire devices, nanoribbon devices, quantum well devices, or other electronic devices.

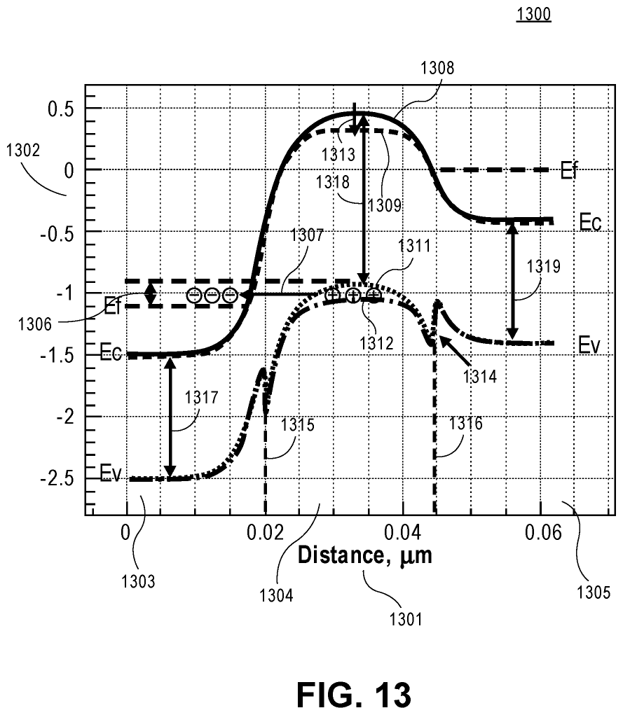

FIG. 13 is a view 1300 illustrating an energy band diagram of the electronic device structure according to one embodiment. As shown in FIG. 13, the energy band diagram includes an energy 1302 of electric current carriers as a function of a distance 1301 along the electronic device structure. The electronic device structure includes a wide bandgap channel region 1304 between a narrow bandgap drain region 1303 and a narrow bandgap source region 1305. In one embodiment, the wide bandgap channel region 1304 represents the wide bandgap channel layer 305, the narrow bandgap drain region 1303 and narrow bandgap source region 1305 represent the narrow bandgap source/drain regions 701 and 702 depicted in FIGS. 8 and 9.

The wide bandgap channel region 1304 is beneath the gate electrode (not shown). As shown in FIG. 13, wide bandgap channel region 1304 is within edges 1315 and 1316 of the gate electrode. As shown in FIG. 13, the narrow bandgap drain region 1303 and the narrow bandgap source region 1305 are outside of the gate electrode edges 1315 and 1316.

As shown in FIG. 13, at the bias voltage Vd substantially equal to about 1.1V (Ef_s at distance 0.065 um−Ef_d at distance 0), the narrow bandgap drain region 1303 has a conduction energy band E_{c} and a valence energy band Eᵥ that are separated by a bandgap Eg 1317, wide bandgap channel region 1304 has a conduction energy band E_{c} and a valence energy band Eᵥ that are separated by a bandgap Eg 1318, narrow bandgap source region 1305 has a conduction energy band E_{c} and a valence energy band Eᵥ that are separated by a bandgap Eg 1319. As shown in FIG. 13, each of the bandgaps 1317, and 1319 is smaller than bandgap Eg 1318. As shown in FIG. 13, the valence band of the wide bandgap channel region 1304 has a valence band offset VBO 1314 relative to the valence band of the narrow bandgap source region 1305 at the edge 1316 of the gate electrode. As shown in FIG. 13, the conduction band Ec of the wide bandgap channel region 1304 has a substantially zero offset relative to the conduction band Ec of each of the narrow bandgap drain region 1303 and the narrow bandgap source region 1305. As shown in FIG. 13, at the gate edge 1316 the valence band of the channel region 1304 and the valence band of the source region 1305 bend away from each other, so that the VBO 1314 has a valley shape. As shown in FIG. 13, at the gate edge 1316 the valence band of the wide bandgap channel region 1304 is lower in energy than the valence band of the narrow bandgap source region 1305. As shown in FIGS. 11 and 13, the VBO 1314 is inverted comparing to the VBO 1110.

As shown in FIG. 13, at the bias voltage Vd—substantially equal to about 1.1V, the valence band in the wide bandgap channel region 1304 is at an energy level 1311, which is above the Fermi level Ef of the narrow bandgap drain region 1303. Because the states above Ef are empty while the states below 1311 are filled with electrons, there exists a BTBT window 1306 between 1311 and the Ef of 1303 within which electrons from the occupied states below 1311 can tunnel to the empty states above the Ef of 1303 through the bandgap 1309 of the wide bandgap channel 1304. As shown in FIG. 13, electrons 1306 tunnel 1307 within the BTBT window 1306 from the valence band Ev of the wide bandgap channel region 1304 through the width of the wide bandgap channel region 1304 to the conduction band Ec of the narrow bandgap drain region 1303 above the Fermi level Ef, leaving behind floating holes 1312 in the wide bandgap channel region 1304. Placing the wide bandgap channel region 1304 between the narrow bandgap source/drain regions to contain the BTBT window 1306 in the substantially high electric field region significantly increases the tunneling width 1307 compared to 1104 in FIG. 11. Placing the wide bandgap channel region 1304 between the narrow bandgap source/drain regions substantially also reduces the BTBT window, as the valence band of the wide bandgap channel region 1304 is moved down to be closer to the Fermi level Ef in the narrow bandgap drain region 1303, reducing the number of available states which valence electrons in 1304 can tunnel to. As shown in FIGS. 11 and 13 the BTBT window 1306 is substantially reduced comparing to the BTBT window 1103.

As shown in FIG. 13, at the bias voltage Vd substantially equal to about 1.1V, the conduction band in the wide bandgap channel region 1304 reduces from an energy level 1308 to an energy level 1309. As shown in FIG. 13, the inverted valley shaped VBO 1314 at the narrow bandgap source region 1305 reduces the barrier for the floating holes 1311 thus reducing the BIBL 1313 comparing to the BIBL 1107. In one embodiment, the barrier for the floating holes is reduced by about the value of the valley shaped VBO. In one embodiment, the barrier for the floating holes is reduced by at least about 0.4 eV.

As shown in FIG. 13, the heterojunction between the wide bandgap channel region 1304 and the narrow bandgap source region 1305 is aligned to the gate edge 1316. The heterojunction between the wide bandgap channel region 1304 and the narrow bandgap drain region 1303 is aligned to the gate edge 1315. That is, the transistor device having the wide bandgap channel region 1304 between the narrow bandgap source/drain regions beneficially reduces the BTBT window without a need for a gate-to-source/drain overlap so that the scalability of the transistor device gate length is not limited by the gate-to-source/drain overlap comparing to conventional devices. The transistor device having the wide bandgap channel region 1304 between the narrow bandgap source/drain regions has the subthreshold slope value and off-state leakage current substantially reduced due to the reduced BTBT and BIBL comparing to conventional devices.

As shown in FIG. 13, the narrow bandgap source region 1305 has substantially zero CBO and low injection mass of the electrical current carriers and the wide bandgap channel region 1304 has substantially small transport mass and higher ballistic velocity of the electrical current carriers that increases the device performance comparing to that of the conventional transistor devices.

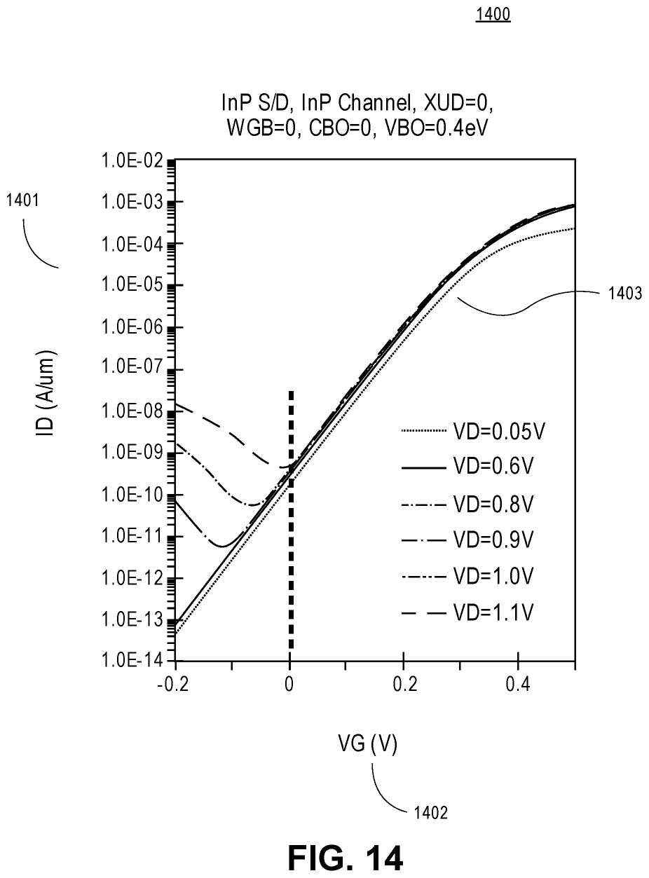

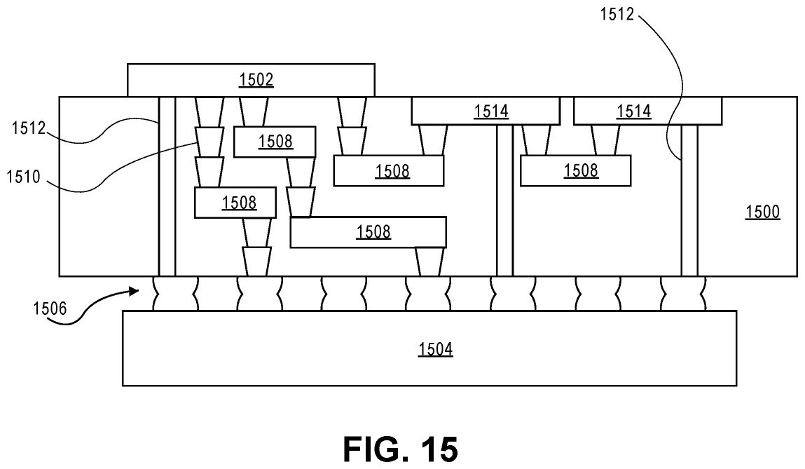

FIG. 14 is a view 1400 of a graph including a set of curves 1403 showing an off-state leakage drain current Id 1401 of a wide bandgap transistor having the narrow bandgap source/drain regions as a function of a gate voltage Vg 1402 at different drain voltages according to one embodiment. In one embodiment, the wide bandgap transistor has a structure that is similar to the wide bandgap electronic device structure depicted in FIGS. 9 and 13. In one embodiment, the transistor has InP channel region and InGaAs source/drain regions, gate-to-source/drain overlap (XUD) is zero, the CBO is about zero and the VBO is about 0.4 eV. As shown in FIG. 14, the off-state drain leakage Id does not increase as the bias voltage between the source and drain Vd increases. As shown in FIG. 15, the off-state leakage current (at Vg=0) does not increase with increasing the drain bias Vd.

FIG. 15 illustrates an interposer 1500 that includes one or more embodiments of the invention. The interposer 1500 is an intervening substrate used to bridge a first substrate 1502 to a second substrate 1504. The first substrate 1502 may be, for instance, an integrated circuit die that includes the transistors as described herein, diodes, memory devices, or other semiconductor devices. The second substrate 1504 may be, for instance, a memory module, a computer motherboard, or another integrated circuit die that includes the transistors, as described herein. Generally, the purpose of an interposer 1500 is to spread a connection to a wider pitch or to reroute a connection to a different connection. For example, an interposer 1500 may couple an integrated circuit die to a ball grid array (BGA) 1506 that can subsequently be coupled to the second substrate 1504. In some embodiments, the first and second substrates 1502/1504 are attached to opposing sides of the interposer 1500. In other embodiments, the first and second substrates 1502/1504 are attached to the same side of the interposer 1500. And in further embodiments, three or more substrates are interconnected by way of the interposer 1500.

The interposer 1500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as but not limited to silicon, germanium, group III-V and group IV materials.

The interposer may include metal interconnects 1508, vias 1510 and through-silicon vias (TSVs) 1512. The interposer 1500 may further include embedded devices 1514, including passive and active devices that include the transistors as described herein. The passive and active devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1500. In accordance with embodiments of the invention, apparatuses or processes disclosed herein may be used in the fabrication of interposer 1500.

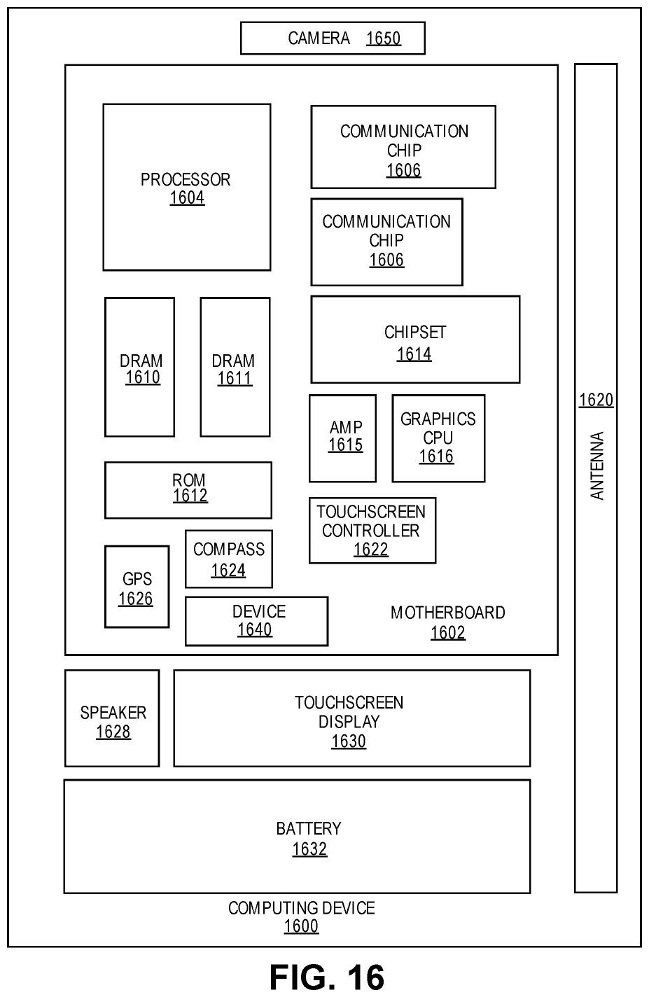

FIG. 16 illustrates a computing device 1600 in accordance with one embodiment of the invention. The computing device 1600 houses a board 1602. The board 1602 may include a number of components, including but not limited to a processor 1604 and at least one communication chip 1606. The processor 1604 is physically and electrically coupled to the board 1602. In some implementations the at least one communication chip is also physically and electrically coupled to the board 1602. In further implementations, at least one communication chip 1606 is part of the processor 1604.

Depending on the application, computing device 1600 may include other components that may or may not be physically and electrically coupled to the board 1602. These other components include, but are not limited to, a memory, such as a volatile memory 1610 (e.g., a DRAM), a non-volatile memory 1612 (e.g., ROM), a flash memory, an exemplary graphics processor 1616, a digital signal processor (not shown), a crypto processor (not shown), a chipset 1614, an antenna 1620, a display, e.g., a touchscreen display 1630, a display controller, e.g., a touchscreen controller 1622, a battery 1632, an audio codec (not shown), a video codec (not shown), an amplifier, e.g., a power amplifier 1615, a global positioning system (GPS) device 1626, a compass 1624, an accelerometer (not shown), a gyroscope (not shown), a speaker 1628, a camera 1650, and a mass storage device (such as hard disk drive, compact disk (CD), digital versatile disk (DVD), and so forth) (not shown).

A communication chip, e.g., communication chip 1606, enables wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1600 may include a plurality of communication chips. For instance, one of the communication chips 1606 may be dedicated to shorter range wireless communications such as Wi-Fi and Bluetooth and the other one of the communication chips 1606 may be dedicated to longer range wireless communications such as GPS, EDGE, GPRS, CDMA, WiMAX, LTE, Ev-DO, and others.

In at least some embodiments, the processor 1604 of the computing device 1600 includes an integrated circuit die having one or more electronic devices, e.g., transistors or other electronic devices, as described herein. The term “processor” may refer to any device or portion of a device that processes electronic data from registers and/or memory to transform that electronic data into other electronic data that may be stored in registers and/or memory.

The communication chip 1606 also includes an integrated circuit die package having the transistors, as described herein. In further implementations, another component housed within the computing device 1600 may contain an integrated circuit die package having the transistors, as described herein. In accordance with one implementation, the integrated circuit die of the communication chip includes one or more electronic devices including the transistors, or other electronic devices, as described herein. In various implementations, the computing device 1600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1600 may be any other electronic device that processes data.

The above description of illustrative implementations of the invention, including what is described in the Abstract, is not intended to be exhaustive or to limit the invention to the precise forms disclosed. While specific implementations of, and examples for the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

The following examples pertain to further embodiments:

In Example 1, an electronic device comprises a channel layer on a buffer layer on a substrate; a source/drain region on the buffer layer, the channel layer comprising a first semiconductor, the source/drain region comprising a second semiconductor that has a bandgap smaller than a bandgap of the first semiconductor; and a gate electrode on the channel layer.

In Example 2, the subject matter of Example 1 can optionally include that first semiconductor has a conduction band that has a zero offset relative to the conduction band of the second semiconductor.

In Example 3, the subject matter of any of Examples 1-2 can optionally include that the first semiconductor has a dopant concentration equal or smaller than 10′16 atoms/cm\hat{ }3.

In Example 4, the subject matter of any of Examples 1-3 can optionally include that each of the first semiconductor and the second semiconductor comprises a III-V semiconductor material.

In Example 5, the subject matter of any of Examples 1-4 can optionally include that the first semiconductor comprises gallium arsenide, indium phosphide, gallium phosphide, indium gallium phosphide, aluminum gallium arsenide, gallium arsenide antimonide (GaAsₓSb₁₋ₓ) (where 0≤x≤1), indium gallium arsenide antimonide (InₓGa₁₋ₓAs_{y}Sb_{1-y}), indium gallium arsenide phosphide (InₓGa₁₋ₓAs_{y}P_{1-y}), indium gallium arsenide phosphide antimonide InₓGa₁₋ₓP_{y}Sb_{1-y} (where 0≤x≤0.3, 0≤y≤1), indium aluminum arsenide antimonide InₓAl₁₋ₓAs_{y}Sb_{1-y}, indium aluminum arsenide phosphide (InₓAl₁₋ₓAs_{y}P_{1-y}) (where 0.8≤x≤1, 0≤y≤1), or any combination thereof.

In Example 6, the subject matter of any of Examples 1-5 can optionally include that the second semiconductor comprises indium gallium arsenide, indium antimonide, indium gallium antimonide, indium gallium arsenide antimonide (InₓGa₁₋ₓAs_{y}Sb_{1-y}), indium gallium arsenide phosphide (InₓGa₁₋ₓAs_{y}P_{1-y}), indium gallium phosphide antimonide (InₓGa₁₋ₓP_{y}Sb_{1-y}), indium aluminum arsenide antimonide (InₓAl₁₋ₓAs_{y}Sb_{1-y}), indium aluminum arsenide phosphide (InₓAl₁₋ₓAs_{y}P_{1-y}), where 0≤x≤1, 0≤y≤1, or any combination thereof.

In Example 7, the subject matter of any of Examples 1-6 can optionally include that a valence band of the first semiconductor is offset relative to a valence band of the second semiconductor by at least 0.4 eV.

In Example 8, the subject matter of any of Examples 1-7 can optionally include a gate dielectric on the channel layer.

In Example 9, the subject matter of Example 8 can optionally include that the gate dielectric wraps around the channel layer.

In Example 10, the subject matter of any of Examples 1-9 can optionally include that the channel layer is a part of a fin, a nanowire, or a nanoribbon.

In Example 11, the subject matter of any of Examples 1-10 can optionally include that the source/drain region is in a recess in the channel layer.

In Example 12, a system comprises a chip including an electronic device comprising a channel layer on a buffer layer on a substrate; a source/drain region on the buffer layer, the channel layer comprising a first semiconductor, the source/drain region comprising a second semiconductor that has a bandgap smaller than a bandgap of the first semiconductor; and a gate electrode on the channel layer.

In Example 13, the subject matter of Example 12 can optionally include that the first semiconductor has a conduction band that has a zero offset relative to the conduction band of the second semiconductor.

In Example 14, the subject matter of any of Examples 12-13 can optionally include that the first semiconductor has a dopant concentration equal or smaller than 10\hat{ }16 atoms/cm\hat{ }3.

In Example 15, the subject matter of any of Examples 12-14 can optionally include that each of the first semiconductor and the second semiconductor comprises a III-V semiconductor material.

In Example 16, the subject matter of any of Examples 12-15 can optionally include that the first semiconductor comprises gallium arsenide, indium phosphide, gallium phosphide, indium gallium phosphide, aluminum gallium arsenide, gallium arsenide antimonide (GaAsₓSb_{1-X}) (where 0≤x≤1), indium gallium arsenide antimonide (InₓGa₁₋ₓAs_{y}Sb_{1-y}), indium gallium arsenide phosphide (InₓGa₁₋ₓAs_{y}P_{1-y}), indium gallium arsenide phosphide antimonide InₓGa₁₋ₓP_{y}Sb_{1-y} (where 0≤x≤0.3, 0≤y≤1), indium aluminum arsenide antimonide InₓAl₁₋ₓAs_{y}Sb_{1-y}, indium aluminum arsenide phosphide (InₓAl₁₋ₓAs_{y}P_{1-y}) (where 0.8≤x≤1, 0≤y≤1), or any combination thereof.

In Example 17, the subject matter of any of Examples 12-16 can optionally include that the second semiconductor comprises indium gallium arsenide, indium antimonide, indium gallium antimonide, indium gallium arsenide antimonide (InₓGa₁₋ₓAs_{y}Sb_{1-y}), indium gallium arsenide phosphide (InₓGa₁₋ₓAs_{y}P_{1-y}), indium gallium phosphide antimonide (InₓGa₁₋ₓP_{y}Sb_{1-y}), indium aluminum arsenide antimonide (InₓAl₁₋ₓAs_{y}Sb_{1-y}), indium aluminum arsenide phosphide (InₓAl₁₋ₓAs_{y}P_{1-y}), where 0≤x≤1, 0≤y≤1, or any combination thereof.

In Example 18, the subject matter of any of Examples 12-17 can optionally include that a valence band of the first semiconductor is offset relative to a valence band of the second semiconductor by at least 0.4 eV.

In Example 19, the subject matter of any of Examples 12-18 can optionally include a gate dielectric on the channel layer.

In Example 20, the subject matter of Example 19 can optionally include that the gate dielectric wraps around the channel layer.

In Example 21, the subject matter of any of Examples 12-20 can optionally include that the channel layer is a part of a fin, a nanowire, or a nanoribbon.

In Example 22, the subject matter of any of Examples 12-21 can optionally include that the source/drain region is in a recess in the channel layer.

In Example 23 a method to manufacture an electronic device comprises depositing a channel layer comprising a first semiconductor on a buffer layer on a substrate; forming a gate electrode on the channel layer; forming a recess in the channel layer; forming a source/drain region in the recess, the source/drain region comprising a second semiconductor that has a bandgap greater than a bandgap of the first semiconductor.

In Example 24, the subject matter of Example 23 can optionally include that the first semiconductor has a conduction band that has a zero offset relative to the conduction band of the second semiconductor.

In Example 25, the subject matter of any of Examples 23-24 can optionally include that the first semiconductor has a dopant concentration equal or smaller than 10′16 atoms/cm\hat{ }3.

In Example 26, the subject matter of any of Examples 23-25 can optionally include that each of the first semiconductor and the second semiconductor comprises a III-V semiconductor material.

In Example 27, the subject matter of any of Examples 23-26 can optionally include that the first semiconductor comprises gallium arsenide, indium phosphide, gallium phosphide, indium gallium phosphide, aluminum gallium arsenide, gallium arsenide antimonide (GaAsₓSb_{1-X}) (where 0≤x≤1), indium gallium arsenide antimonide (InₓGa₁₋ₓAs_{y}Sb_{1-y}), indium gallium arsenide phosphide (InₓGa₁₋ₓAs_{y}P_{1-y}), indium gallium arsenide phosphide antimonide InₓGa₁₋ₓP_{y}Sb_{1-y} (where 0≤x≤0.3, 0≤y≤1), indium aluminum arsenide antimonide InₓAl₁₋ₓAs_{y}Sb_{1-y}, indium aluminum arsenide phosphide (InₓAl₁₋ₓAs_{y}P_{1-y}) (where 0.8≤x≤1, 0≤y≤1), or any combination thereof.

In Example 28, the subject matter of any of Examples 23-27 can optionally include that the second semiconductor comprises indium gallium arsenide, indium antimonide, indium gallium antimonide, indium gallium arsenide antimonide (InₓGa₁₋ₓAs_{y}Sb_{1-y}), indium gallium arsenide phosphide (InₓGa₁₋ₓAs_{y}P_{1-y}), indium gallium phosphide antimonide (InₓGa₁₋ₓP_{y}Sb_{1-y}), indium aluminum arsenide antimonide (InₓAl₁₋ₓAs_{y}Sb_{1-y}), indium aluminum arsenide phosphide (InₓAl₁₋ₓAs_{y}P_{1-y}), where 0≤x≤1, 0≤y≤1, or any combination thereof.

In Example 29, the subject matter of any of Examples 23-28 can optionally include that a valence band of the first semiconductor is offset relative to a valence band of the second semiconductor by at least 0.4 eV.

In Example 30, the subject matter of any of Examples 23-29 can optionally include forming a spacer on the gate electrode; and etching a portion of the channel layer outside the gate electrode to form a recess.

In Example 31, the subject matter of any of Examples 23-30 can optionally include that the channel layer is a part of a fin, a nanowire, or a nanoribbon.

In Example 32, the subject matter of any of Examples 23-31 can optionally include removing the gate electrode; depositing a gate dielectric on the channel layer; and forming a metal gate stack on the gate dielectric.

In the foregoing specification, methods and apparatuses have been described with reference to specific exemplary embodiments thereof. It will be evident that various modifications may be made thereto without departing from the broader spirit and scope of embodiments as set forth in the following claims. The specification and drawings are, accordingly, to be regarded in an illustrative sense rather than a restrictive sense.

What is claimed is:

1. An electronic device comprising:
a first layer on a substrate, the first layer comprising a first semiconductor material; and
a source region or a drain region on the substrate, the source region or drain region comprising a second semiconductor material that has a bandgap smaller than a bandgap of the first semiconductor material; and
a gate electrode on the first layer.

2. The electronic device of claim 1, wherein the first semiconductor material has a conduction band that has a zero offset relative to the conduction band of the second semiconductor material.

3. The electronic device of claim 1, wherein the first semiconductor material has a dopant concentration equal or smaller than 10\hat{ }16 atoms/cm\hat{ }3.

4. The electronic device of claim 1, wherein each of the first semiconductor material and the second semiconductor material comprises a III-V semiconductor material.

5. The electronic device of claim 1, wherein the first semiconductor material comprises gallium arsenide, indium phosphide, gallium phosphide, indium gallium phosphide, aluminum gallium arsenide, gallium arsenide antimonide (GaAsₓSb₁₋ₓ) (where 0≤x≤1), indium gallium arsenide antimonide (InₓGa₁₋ₓAs_{y}Sb_{1-y}), indium gallium arsenide phosphide (InₓGa₁₋ₓAs_{y}P_{1-y}), indium gallium arsenide phosphide antimonide InₓGa₁₋ₓP_{y}Sb_{1-y} (where 0≤x≤0.3, 0≤y≤1), indium aluminum arsenide antimonide InₓAl₁₋ₓAs_{y}Sb_{1-y}, indium aluminum arsenide phosphide (InₓAl₁₋ₓAs_{y}P_{1-y}) (where 0.8≤x≤1, 0≤y≤1), or any combination thereof.

6. The electronic device of claim 1, wherein the second semiconductor material comprises indium gallium arsenide, indium antimonide, indium gallium antimonide, indium gallium arsenide antimonide (InₓGa₁₋ₓAs_{y}Sb_{1-y}), indium gallium arsenide phosphide (InₓGa₁₋ₓAs_{y}P_{1-y}), indium gallium phosphide antimonide (InₓGa₁₋ₓP_{y}Sb_{1-y}), indium aluminum arsenide antimonide (InₓAl₁₋ₓAs_{y}Sb_{1-y}), indium aluminum arsenide phosphide (InₓAl₁₋ₓAs_{y}P_{1-y}), where 0≤x≤1, 0≤y≤1, or any combination thereof.

7. The electronic device of claim 1, wherein a valence band of the first semiconductor material is offset relative to a valence band of the second semiconductor material by at least 0.4 eV.

8. The electronic device of claim 1, further comprising
a gate dielectric on the first layer.

9. The electronic device of claim 1, wherein the first layer is a part of a fin, a nanowire, or a nanoribbon.

10. The electronic device of claim 1, wherein the source region or drain region is in a recess in the first layer.

11. A system comprising:
a chip including
an electronic device comprising
a first layer on a substrate; and
a source region or a drain region on the substrate, the first layer comprising a first semiconductor material, the source region or drain region comprising a second semiconductor material that has a bandgap smaller than a bandgap of the first semiconductor material; and
a gate electrode on the first layer.

12. The system of claim 11, wherein the first semiconductor material has a conduction band that has a zero offset relative to the conduction band of the second semiconductor material.

13. The system of claim 11, wherein each of the first semiconductor material and the second semiconductor material comprises a III-V semiconductor material.

14. The system of claim 11, wherein the first semiconductor material comprises gallium arsenide, indium phosphide, gallium phosphide, indium gallium phosphide, aluminum gallium arsenide, gallium arsenide antimonide (GaAsₓSb₁₋ₓ) (where 0≤x≤1), indium gallium arsenide antimonide (InₓGa₁₋ₓAs_{y}Sb_{1-y}), indium gallium arsenide phosphide (InₓGa₁₋ₓAs_{y}P_{1-y}), indium gallium arsenide phosphide antimonide InₓGa₁₋ₓP_{y}Sb_{1-y} (where 0≤x≤0.3, 0≤y≤1), indium aluminum arsenide antimonide InₓAl₁₋ₓAs_{y}Sb_{1-y}, indium aluminum arsenide phosphide (InₓAl₁₋ₓAs_{y}P_{1-y}) (where 0.8≤x≤1, 0≤y≤1), or any combination thereof.

15. The system of claim 11, wherein the second semiconductor material comprises indium gallium arsenide, indium antimonide, indium gallium antimonide, indium gallium arsenide antimonide (InₓGa₁₋ₓAs_{y}Sb_{1-y}), indium gallium arsenide phosphide (InₓGa₁₋ₓAs_{y}P_{1-y}), indium gallium phosphide antimonide (InₓGa₁₋ₓP_{y}Sb_{1-y}), indium aluminum arsenide antimonide (InₓAl₁₋ₓAs_{y}Sb_{1-y}), indium aluminum arsenide phosphide (InₓAl₁₋ₓAs_{y}P_{1-y}), where 0≤x≤1, 0≤y≤1, or any combination thereof.

16. The system of claim 11, wherein a valence band of the first semiconductor material is offset relative to a valence band of the second semiconductor material by at least 0.4 eV.

17. The system of claim 11, further comprising
a gate dielectric on the first layer.

18. A method to manufacture an electronic device, comprising:
depositing a first layer comprising a first semiconductor material on a substrate;
forming a gate electrode on the first layer;
forming a recess in the first layer;
forming a source region or a drain region in the recess, the source region or drain region comprising a second semiconductor material that has a bandgap greater than a bandgap of the first semiconductor material.

19. The method of claim 18, wherein the first semiconductor material has a conduction band that has a zero offset relative to the conduction band of the second semiconductor material.

20. The method of claim 18, wherein each of the first semiconductor material and the second semiconductor material comprises a III-V semiconductor material.

21. The method of claim 18, wherein the first semiconductor material comprises gallium arsenide, indium phosphide, gallium phosphide, indium gallium phosphide, aluminum gallium arsenide, gallium arsenide antimonide (GaAsₓSb₁₋ₓ) (where 0≤x≤1), indium gallium arsenide antimonide (InₓGa₁₋ₓAs_{y}Sb_{1-y}), indium gallium arsenide phosphide (InₓGa₁₋ₓAs_{y}P_{1-y}), indium gallium arsenide phosphide antimonide InₓGa₁₋ₓP_{y}Sb_{1-y} (where 0≤x≤0.3, 0≤y≤1), indium aluminum arsenide antimonide InₓAl₁₋ₓAs_{y}Sb_{1-y}, indium aluminum arsenide phosphide (InₓAl₁₋ₓAs_{y}P_{1-y}) (where 0.8≤x≤1, 0≤y≤1), or any combination thereof.

22. The method of claim 18, wherein the second semiconductor material comprises indium gallium arsenide, indium antimonide, indium gallium antimonide, indium gallium arsenide antimonide (InₓGa₁₋ₓAs_{y}Sb_{1-y}), indium gallium arsenide phosphide (InₓGa₁₋ₓAs_{y}P_{1-y}), indium gallium phosphide antimonide (InₓGa₁₋ₓP_{y}Sb_{1-y}), indium aluminum arsenide antimonide (InₓAl₁₋ₓAs_{y}Sb_{1-y}), indium aluminum arsenide phosphide (InₓAl₁₋ₓAs_{y}P_{1-y}), where 0≤x≤1, 0≤y≤1, or any combination thereof.

23. The method of claim 18, wherein a valence band of the first semiconductor material is offset relative to a valence band of the second semiconductor material by at least 0.4 eV.

24. The method of claim 18, further comprising:
forming a spacer on the gate electrode; and
etching a portion of the first layer outside the gate electrode to form a recess.

25. The method of claim 18, further comprising
removing the gate electrode;
depositing a gate dielectric on the first layer; and
forming a metal gate stack on the gate dielectric.
